(19) United States
(12) Patent Application Publication
(10) Pub. No.: US 2025/0044389 A1
(43) Pub. Date: Feb. 6, 2025

(54) PARALLEL TRANSMIT RADIO FREQUENCY PULSE DESIGN WITH DEEP LEARNING

(71) Applicant: Regents of the University of Minnesota, Minneapolis, MN (US)

(72) Inventors: Mehmet Akcakaya, Minneapolis, MN (US); Kamil Ugurbil, Minneapolis, MN (US)

(21) Appl. No.: 18/696,252

(22) PCT Filed: Sep. 27, 2022
(86) PCT No.: PCT/US2022/044928

§ 371 Date: Mar. 27, 2024

Related U.S. Application Data
(60) Provisional application No. 63/248,931, filed on Sep. 27, 2021.

(51) Int. Cl. G01R 33/54; G01R 33/56

(52) U.S. Cl. CPC G01R 33/543; G01R 33/5607

(57) ABSTRACT

Parallel transmit (“pTx”) radio frequency (“RF”) pulses, or other RF pulse types, for use in magnetic resonance imaging (“MRI”) are designed using deep learning techniques. In some aspects, deep learning can be used to determine optimization parameters for improving the computational efficiency of solving a physics-based constrained optimization problem for generating RF pulse waveforms. In some other aspects, deep learning can be used to learn a mapping from magnetic resonance data obtained with an MRI system to pTx RF pulse waveforms in a data-driven manner. The mapping can be based on field map data that are inherently encoded in scout images without having to explicitly calculate the field maps, or may be based on multichannel B₁⁺ maps that are concatenated along one spatial dimension, such as the y-dimension.

### CROSS-REFERENCE TO RELATED APPLICATIONS

This application claims the benefit of U.S. Provisional Patent Application Ser. No. 63/248,931, filed on Sep. 27, 2021, and entitled “PARALLEL TRANSMIT RADIO FREQUENCY PULSE DESIGN WITH DEEP LEARNING,” which is herein incorporated by reference in its entirety.

### STATEMENT REGARDING FEDERALLY SPONSORED RESEARCH

This invention was made with government support under EB027061 awarded by the National Institutes of Health. The government has certain rights in the invention.

### BACKGROUND

Magnetic field inhomogeneity associated with radiofrequency (“RF”) waves (e.g., B₁ inhomogeneity) is a significant issue in so-called high (e.g., 3 to 7 Tesla) and ultrahigh-field (“UHF”) magnetic resonance imaging (“MRI”), which may refer to MRI scanners operating at magnetic field strengths of 7 T or greater. The use of parallel transmit (“pTx”) RF pulses offers a potential solution for this problem. Using the differences in the profiles of multiple transmit coils, a homogenous field for a target magnetization profile can be achieved with the appropriate pulse design. The pulse design needs to be performed to match the target magnetization as closely as possible while satisfying physical constraints due to power deposition. This requires solving a quadratically constrained optimization problem, which is time-consuming. This has hindered the translation of pTx to broader use, as the application of these techniques at the MRI scanner require substantial expertise.

Thus, efforts have been made to make pTx more user-friendly and less time-consuming. Early work included a focus on universal pulse designs that were aimed to work over a dictionary of subjects. However, the performance of such pulses cannot match the individually tailored optimization-based pulse design. Recent works have instead focused on using deep learning for fast generation of such pulses. Existing approaches use a simple neural network to learn appropriate pulse shapes from given transmit coil profiles with no explicit incorporation of the physics of the problem. Physics-guided methods may provide an additional degree of robustness, but they also do not enforce the power-related constraints explicitly, which are needed to ensure the safety of the participants.

### SUMMARY OF THE DISCLOSURE

The present disclosure addresses the aforementioned drawbacks by providing a method for generating parallel transmit (pTx) radio frequency (RF) pulse waveforms for use with a magnetic resonance imaging (MRI) system. The method includes accessing field map data with a computer system, where the field map data indicate at least one B₀ field map associated with the MRI system and at least one B₁⁺ field map associated with an RF coil. An optimization problem is constructed with the computer system, where the optimization problem includes an objective function having at least one physics-based constraint. A trained neural network is accessed with the computer system, where the trained neural network has been trained on training data in order to learn a mapping from field map data to parameters for improving an efficiency of solving a constrained optimization problem. The field map data are then applied to the trained neural network using the computer system, generating output as optimization parameter data that indicate parameters for improving the efficiency of solving the optimization problem constructed with the computer system. One or more pTx RF pulse waveforms are then generated by using the computer system to solve the optimization problem based on the optimization parameter data. The pTx RF pulse waveforms are then stored for use by the MRI system.

It is another aspect of the present disclosure to provide a method for generating pTx RF pulse waveforms for use with an MRI system. The method includes accessing magnetic resonance data with a computer system, where the magnetic resonance data are acquired with an MRI system. A neural network is accessed with the computer system, where the neural network has been trained on training data in order to learn a mapping from magnetic resonance data to pTx RF pulse waveforms. The magnetic resonance data are applied to the neural network using the computer system, generating output as pTx RF pulse waveforms. The pTx RF pulse waveforms are then stored for use by the MRI system.

It is another aspect of the present disclosure to provide a method for generating RF pulse waveforms for use with an MRI system. The method includes accessing field map data with a computer system, where the field map data indicate at least one B₀ field map associated with the MRI system and at least one B₁⁺ field map associated with an RF coil. An optimization problem is constructed with the computer system, where the optimization problem includes an objective function having at least one physics-based constraint. A trained neural network is accessed with the computer system, where the trained neural network has been trained on training data in order to learn a mapping from field map data to parameters for improving an efficiency of solving a constrained optimization problem. The field map data are then applied to the trained neural network using the computer system, generating output as optimization parameter data that indicate parameters for improving the efficiency of solving the optimization problem constructed with the computer system. One or more RF pulse waveforms are then generated by using the computer system to solve the optimization problem based on the optimization parameter data. The RF pulse waveforms are then stored for use by the MRI system. The RF pulse wave forms may be indicative of pTx RF pulses or other RF pulse types, such as water-fat separation RF pulses.

The foregoing and other aspects and advantages of the present disclosure will appear from the following description. In the description, reference is made to the accompanying drawings that form a part hereof, and in which there is shown by way of illustration a preferred embodiment. This embodiment does not necessarily represent the full scope of the invention, however, and reference is therefore made to the claims and herein for interpreting the scope of the invention.

### BRIEF DESCRIPTION OF THE DRAWINGS

FIG. 1 is a flowchart of an example method for generating pTx RF pulse waveforms by solving a physics-based constrained optimization based on optimization parameters that are learned from field map data using deep learning, such as by using a suitably trained neural network.

FIG. 2 is a flowchart of an example method for training a neural network to learn a mapping from field map data to optimization parameters for improving the efficiency of solving a physics-based constrained optimization problem.

FIG. 3 is a flowchart of an example method for generating pTx RF pulse waveforms by applying scout images to a neural network that has been trained to map scout images to pTx RF pulse waveforms based on field map data encoded in the scout images without having to explicitly calculate the field map data.

FIG. 4 is a flowchart of an example method for training a neural network to learn a mapping from scout image data to pTx RF pulse waveforms.

FIG. 5 is a workflow diagram illustrating an example neural network that can be used to design pTx RF pulses. In this example, B₁⁺ maps of different coils are concatenated in the y-dimension for shift-invariant processing. Real and imaginary parts are concatenated in the channel dimension.

FIG. 6 is a block diagram of an example system for generating pTx RF pulse waveforms using deep learning techniques.

FIG. 7 is a block diagram of example components that can implement the system of FIG. 6.

FIG. 8 is a block diagram of an example MRI system that can be used to generate pTx RF pulses based on pTx RF pulse waveforms generated using the methods described in the present disclosure.

### DETAILED DESCRIPTION

Described here are systems and method for designing radio frequency (“RF”) pulses for use in magnetic resonance imaging (“MRI”). More particularly, the systems and methods described in the present disclosure enable the fast design of parallel transmit (“pTx”) RF pulses for MRI, which in some instances may be high-field (e.g., 3 to 7 Tesla) and/or ultrahigh-field (“UHF”) MRI. In general, UHF MRI can include MRI systems operating with main magnetic field strengths of 7 T and greater. Additionally or alternatively, the systems and methods described in the present disclosure can also enable the fast design of other RF pulses for MRI, including RF pulses for spatially-selective excitation (e.g., reduced field-of-view imaging, localized magnetic resonance spectroscopy), spectrally-selective excitation (e.g., water-fat separation, water-only excitation, fat suppression), and the like.

In some embodiments, the systems and methods described in the present disclosure implement physics-constrained deep learning (“DL”) algorithms for the design of pTx or other RF pulses that explicitly incorporate the physics of the problem and power or other constraints. The physics-constrained optimization problem for designing these pTx or other RF pulses is unrolled for a fixed number of steps such that it has fixed complexity. It is an advantage of the systems and methods described in the present disclosure that these step sizes in this unrolled optimization problem can be learned using deep learning, such as via one or more neural networks. As a result, the optimization problem still incorporates the physics and power constraints, but because of the learned step sizes for the unrolling, the optimization problem can converge on a solution with greater computational efficiency than would otherwise be attainable. Thus, the systems and methods described in the present disclosure enable the generation of optimized pTx or other RF pulses quickly using deep learning, but done in a way that still incorporates all the information that would normally be used in solving the optimization problem, including the encoding matrix and the power constraints. Advantageously, this technique improves upon existing deep learning-based methods for RF pulse design that do not incorporate such information in terms of performance, while having similar running time (e.g., on the order of milliseconds).

As a non-limiting example, the process for designing pTx RF pulses, or other RF pulse types, includes solving a physics-constrained optimization problem that depicts the target magnetization goal (in magnitude), such as the following:

$${min}_{x} f ( x ) := {‖ \vert bl ( x ) \vert - θ ‖}_{2}^{2} ; \qquad ( 1 )$$

where bl(⋅) is a non-linear Bloch simulation operator that depends on the subject-specific B₀ and B₁⁺ maps, and θ is the target flip angle. As noted above, the optimization incorporates physics-based constraints, such as the following SAR and power constraints:

$$x ∈ {p}^{}$$

$${c}_{i} ( x ) \leq 3 W / kg for i ∈ \{ 1 , … , {N}_{VOPs} \} ,$$

$${c}_{G} ( x ) \leq 1 W / kg$$

$${c}_{pw , k} ( x ) \leq 2 W for k ∈ \{ 1 , … , {N}_{c} \}$$

$${c}_{A , j} ( x ) \leq 1 for j ∈ \{ 1 , … , {N}_{c} \times {V}_{{k}_{T}} \}$$

The functions cᵢ(x), c_{G}(x), c_{pw,k}(x), and c_{A,j}(x) are quadratic functions. They denote the 10-g SAR constraints over virtual observation points (“VOPs”) the VOPs (calculated with Q_{VOPs} Q-matrix), the global SAR constraint (calculated with the Q_{G} Q-matrix), the average power constraint for the kth channel (here taken as 2 W), and the amplitude constraint for the kth channel, respectively.

Additionally or alternatively, other physics-based constraints could be implemented, including constraints related to other physical processes or properties of the RF pulses being designed. As one example, other physics-based constraints may include constraints related to water-fat separation, such as constraints related to resonance frequencies, chemical shifts, phases of water and/or fat signals, and so on. Additionally or alternatively, other physics-based constraints related to spatially-selective excitation and/or spectrally-selective excitation can be implemented.

There are several strategies that can be implemented to solve this optimization problem. It is an aspect of the present disclosure to obtain a solution by solving the constrained optimization problem using a suitable technique (e.g., an interior-point method) while using deep learning to determine a computationally efficient manner in which to solve each particular optimization problem. For example, using an optimization technique such as an interior-point method, which is a lengthy optimization procedure, deep learning can be used to determine a more limited number of iterations needed to run the optimization method. As an example, deep learning can be used to learn the “step sizes” in the optimization algorithm (e.g., by using neural networks), where these step sizes will be functions of the B₀ and B₁⁺ maps. In this way, the hard constraints on SAR and power are satisfied while utilizing a model-based optimization procedure that can generalize better than data-driven methods.

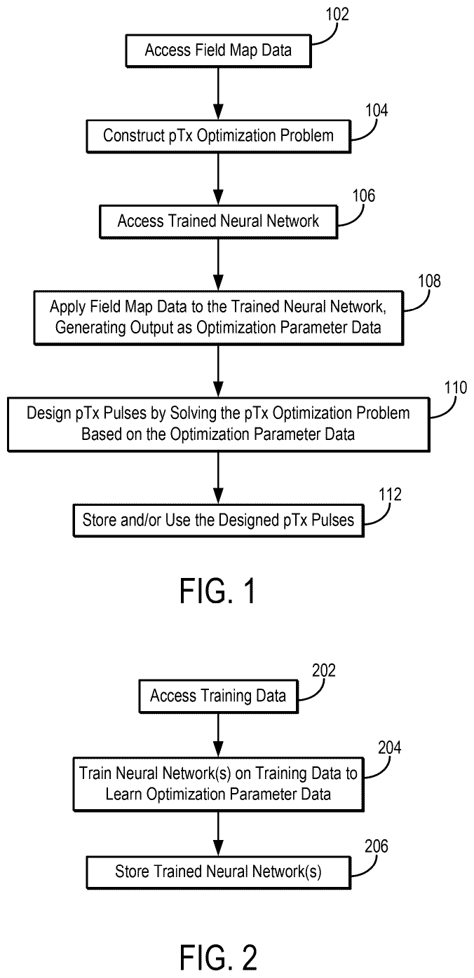

Referring now to FIG. 1, a flowchart is illustrated as setting forth the steps of an example method for designing pTx RF pulses, or other RF pulse types, using a physics-based constrained optimization problem that is solved using a technique whose optimization parameters have been learned using a suitably trained neural network or other machine learning algorithm.

The method includes accessing field map data with a computer system, as indicated at step 102. Accessing the field map data may include retrieving such data from a memory or other suitable data storage device or medium. Alternatively, accessing the field map data may include acquiring such data with an MRI system and transferring or otherwise communicating the data to the computer system, which may be a part of the MRI system. As an example, the field map data can include B₀ maps and B₁⁺ maps.

An optimization problem for designing one or more pTx RF pulses is then constructed by the computer system, as indicated at step 104. Constructing the optimization problem may include selecting the desired objective function for the optimization problem and initializing the relevant parameters. For example, the optimization problem can be constructed by selecting an objective function such as the one in Eqn. (1) and then initializing the relevant parameters for the physics-based constraints. Initializing the constraints can include, for example, setting or otherwise selecting constrains on SAR, power, and other parameters relevant for the pTx design.

A trained neural network (or other suitable machine learning algorithm) is then accessed with the computer system, as indicated at step 106. Accessing the trained neural network may include accessing network parameters (e.g., weights, biases, or both) that have been optimized or otherwise estimated by training the neural network on training data. In some instances, retrieving the neural network can also include retrieving, constructing, or otherwise accessing the particular neural network architecture to be implemented. For instance, data pertaining to the layers in the neural network architecture (e.g., number of layers, type of layers, ordering of layers, connections between layers, hyperparameters for layers) may be retrieved, selected, constructed, or otherwise accessed.

In general, the neural network is trained, or has been trained, on training data in order to learn optimization parameters for efficiently solving a particular optimization problem, such as an optimization problem having the form or structure of the problem constructed by the computer system in step 104. As an example, the neural network can be trained to determine optimal step sizes for solving the optimization problem using a particular optimization technique, such as an interior-point method or the like.

The field map data are then input to the one or more trained neural networks, generating output as optimization parameter data, as indicated at step 108. For example, the optimization parameter data may include optimal step sizes for converging on a solution to the constructed optimization problem in a computationally efficient manner.

One or more pTx RF pulses, or other RF pulse types, are then designed or otherwise constructed by solving the constructed optimization problem using the computer system and based on the optimization parameter data, as indicated at step 110. For example, the designed pTx RF pulses can include RF waveforms for the one or more pTx RF pulses. Additionally or alternatively, the designed RF pulses can include RF waveforms associated with other RF pulse types, such as RF pulses amenable for spatially-selective excitation, spectrally-selective excitation (e.g., as may be used in water-fat separation techniques), magnetization preparation, simultaneous multislice imaging, or the like.

The designed pTx RF pulses, or other RF pulse types, are then stored for later use or used by an MRI system to generate RF pulses based on the RF waveforms of the designed RF pulse waveforms, or both, as indicated at step 112.

Referring now to FIG. 2, a flowchart is illustrated as setting forth the steps of an example method for training one or more neural networks (or other suitable machine learning algorithms) on training data, such that the one or more neural networks are trained to receive input as field map data in order to generate output as optimization parameter data indicating parameters for efficiently solving a physics-based constrained optimization problem for pTx pulse, or other RF pulse type, design.

In general, the neural network(s) can implement any number of different neural network architectures. For instance, the neural network(s) could implement a convolutional neural network, a residual neural network, and the like. In some instances, the neural network(s) may implement deep learning.

Alternatively, the neural network(s) could be replaced with other suitable machine learning algorithms, including those based on supervised learning, unsupervised learning, deep learning, ensemble learning, dimensionality reduction, and so on.

The method includes accessing training data with a computer system, as indicated at step 202. Accessing the training data may include retrieving such data from a memory or other suitable data storage device or medium. Alternatively, accessing the training data may include acquiring such data with an MRI system and transferring or otherwise communicating the data to the computer system, which may be a part of the MRI system.

In general, the training data can include field map data, such as B₀ maps obtained for MRI systems of various field strengths (e.g., 1.5 T, 3 T, 4 T, 7 T, 9.4 T, 10.5 T) and B₁⁺ maps obtained for various configurations and using various different RF transmission hardware.

Additionally or alternatively, accessing the training data can include assembling training data from field map data and other suitable data using a computer system. This step may include assembling the field map data into an appropriate data structure on which the machine learning algorithm can be trained. Assembling the training data may include assembling field map data and other relevant data. For instance, assembling the training data may include generating labeled data and including the labeled data in the training data. Labeled data may include field map data or other relevant data that have been labeled as belonging to, or otherwise being associated with, one or more different classifications or categories. The labeled data may include labeling all data within a field-of-view of the field map data, or may include labeling only those data in one or more regions-of-interest within the field map data. The labeled data may include data that are classified on a voxel-by-voxel basis, or a regional or larger volume basis.

One or more neural networks (or other suitable machine learning algorithms) are trained on the training data, as indicated at step 204. In general, the neural network can be trained by optimizing network parameters (e.g., weights, biases, or both) based on minimizing a loss function. As one non-limiting example, the loss function may be a mean squared error loss function.

Training a neural network may include initializing the neural network, such as by computing, estimating, or otherwise selecting initial network parameters (e.g., weights, biases, or both). Training data can then be input to the initialized neural network, generating output as optimization parameter data. The quality of the optimization parameter data can then be evaluated, such as by passing the optimization parameter data to the loss function to compute an error. The current neural network can then be updated based on the calculated error (e.g., using backpropagation methods based on the calculated error). For instance, the current neural network can be updated by updating the network parameters (e.g., weights, biases, or both) in order to minimize the loss according to the loss function. When the error has been minimized (e.g., by determining whether an error threshold or other stopping criterion has been satisfied), the current neural network and its associated network parameters represent the trained neural network.

The one or more trained neural networks are then stored for later use, as indicated at step 206. Storing the neural network(s) may include storing network parameters (e.g., weights, biases, or both), which have been computed or otherwise estimated by training the neural network(s) on the training data. Storing the trained neural network(s) may also include storing the particular neural network architecture to be implemented. For instance, data pertaining to the layers in the neural network architecture (e.g., number of layers, type of layers, ordering of layers, connections between layers, hyperparameters for layers) may be stored.

The methods described above solve a physics-based constrained optimization problem in order to design or otherwise determine pTx waveforms. In other instances, the pTx waveforms can be determined in a data-driven manner. For example, based on B₀ and B₁⁺ maps, a mapping to the pTx RF waveforms can be directly learned using deep learning techniques. These approaches require no computation of the bl(⋅) term descried above, explicitly. As such, these techniques are data-driven in the sense that they do not require the explicit calculation of the aforementioned optimization problem.

Obtaining B₀ and B₁⁺ maps to implement this data-driven approach to generating pTx pulse waveforms can be time-consuming. It is another aspect of the present disclosure to provide a method for generating pTx pulse waveforms based on a data-driven approach that takes scout images as input, rather than B₀ and B₁⁺ maps. In these embodiments, the B₀ and B₁⁺ maps are effectively encoded in the scout images, and a suitable neural network, or other machine learning algorithm, is trained to derive the encoded information from the scout images and determine one or more pTx pulse waveforms that work best based on the B₀ and B₁⁺ information encoded in the scout images.

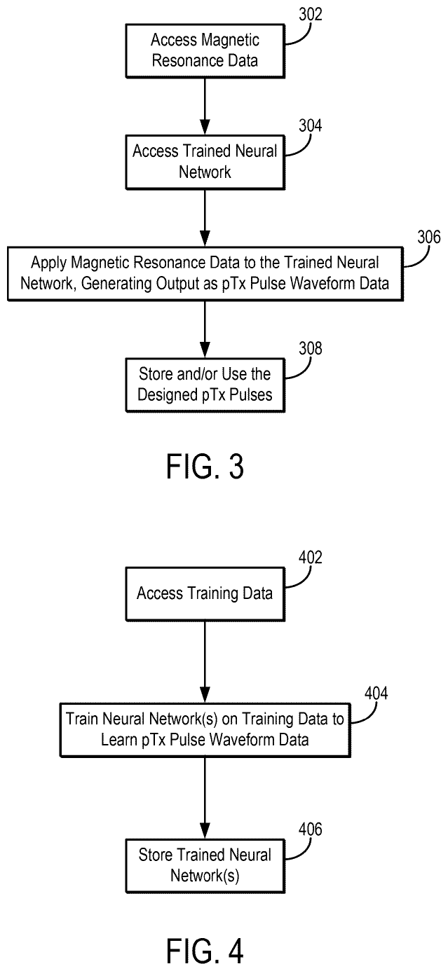

Referring now to FIG. 3, a flowchart is illustrated as setting forth the steps of an example method for designing pTx RF pulses using a faster mapping technique in which a mapping to pTx pulse waveforms is generated from magnetic resonance using a suitably trained neural network or other machine learning algorithm. The input magnetic resonance data may be scout images, multichannel B₁⁺ maps, or the like.

The method includes accessing magnetic resonance data with a computer system, as indicated at step 302. Accessing the magnetic resonance data may include retrieving such data from a memory or other suitable data storage device or medium. Alternatively, accessing the magnetic resonance data may include acquiring such data with an MRI system and transferring or otherwise communicating the data to the computer system, which may be a part of the MRI system. As one non-limiting example, the magnetic resonance data can include low-resolution scout, or localizer, images obtained with an MRI system (e.g., scout image data). As another non-limiting example, the magnetic resonance data can include multichannel B₁⁺ maps.

A trained neural network (or other suitable machine learning algorithm) is then accessed with the computer system, as indicated at step 304. Accessing the trained neural network may include accessing network parameters (e.g., weights, biases, or both) that have been optimized or otherwise estimated by training the neural network on training data. In some instances, retrieving the neural network can also include retrieving, constructing, or otherwise accessing the particular neural network architecture to be implemented. For instance, data pertaining to the layers in the neural network architecture (e.g., number of layers, type of layers, ordering of layers, connections between layers, hyperparameters for layers) may be retrieved, selected, constructed, or otherwise accessed.

In general, the neural network is trained, or has been trained, on training data in order to learn pTx pulse waveforms from scout images that inherently encode information about B₀ and B₁⁺ without having to explicitly measure B₀ and B₁⁺ maps. Additionally or alternatively, the neural network is trained, or has been trained, on training data in order to learn pTx pulse waveforms from multichannel B₁⁺ maps. In some embodiments, the neural network can be trained on multichannel B₁⁺ maps that can been concatenated along a spatial dimension (e.g., the y-dimension) to yield 2D data.

The magnetic resonance data are then input to the one or more trained neural networks, generating output as pTx pulse waveforms, as indicated at step 306. For example, the output pTx pulses waveforms can include RF waveforms for one or more pTx pulses that work best based on the available data encoded in the scout images or other magnetic resonance data.

The designed pTx RF pulses are then stored for later use or used by an MRI system to generate RF pulses based on the RF waveforms of the designed pTx pulses, or both, as indicated at step 308.

Referring now to FIG. 4, a flowchart is illustrated as setting forth the steps of an example method for training one or more neural networks (or other suitable machine learning algorithms) on training data, such that the one or more neural networks are trained to receive input as scout image data, multichannel B₁⁺ maps, or other magnetic resonance data in order to generate output as pTx pulse waveforms.

In general, the neural network(s) can implement any number of different neural network architectures. For instance, the neural network(s) could implement a convolutional neural network, a residual neural network, and the like. In some instances, the neural network(s) may implement deep learning. As non-limiting examples, the neural network can be a neural network classifier that may be based on a U-Net architecture, a ResNet architecture, or the like.

Alternatively, the neural network(s) could be replaced with other suitable machine learning algorithms, including those based on supervised learning, unsupervised learning, deep learning, ensemble learning, dimensionality reduction, and so on. For example, a machine learning classifier that is trained using supervised learning could be implemented.

The method includes accessing training data with a computer system, as indicated at step 402. Accessing the training data may include retrieving such data from a memory or other suitable data storage device or medium. Alternatively, accessing the training data may include acquiring such data with an MRI system and transferring or otherwise communicating the data to the computer system, which may be a part of the MRI system.

In one non-limiting example, the training data can include scout images obtained with one or more MRI systems using different acquisition parameters (e.g., echo time, flip angle) and additionally or alternatively at various different field strengths (e.g., 1.5 T, 3 T, 4 T, 7 T, 9.4 T, 10.5 T). The training data can also include field map data, such as B₀ maps and B₁⁺ maps. For instance, the training data can include multichannel B₁⁺ maps, B₁⁺ (x,y,c). It is an advantage of the present disclosure that the multichannel B₁⁺ maps can be concatenated along a single spatial dimension (e.g., the y-dimension) to provide the multichannel B₁⁺ maps as 2D data that are amenable for training a neural network such as a convolutional neural network.

Additionally or alternatively, accessing the training data can include assembling training data from scout image data, field map data, multichannel B₁⁺ map data, and/or other relevant data using a computer system. This step may include assembling the scout image data, field map data, and/or multichannel B₁⁺ map data into an appropriate data structure on which the machine learning algorithm can be trained. Assembling the training data may include assembling scout image data, field map data, multichannel By map data, and/or other relevant data. For instance, assembling the training data may include generating labeled data and including the labeled data in the training data. Labeled data may include scout image data, field map data, multichannel B₁⁺ map data, and/or other relevant data that have been labeled as belonging to, or otherwise being associated with, one or more different classifications or categories. The labeled data may include labeling all data within a field-of-view of the scout image data. field map data, and/or multichannel B₁⁺ map data or may include labeling only those data in one or more regions-of-interest within the scout image data, field map data, and/or multichannel B₁⁺ map data. The labeled data may include data that are classified on a voxel-by-voxel basis, or a regional or larger volume basis.

One or more neural networks (or other suitable machine learning algorithms) are trained on the training data, as indicated at step 404. In general, the neural network can be trained by optimizing network parameters (e.g., weights, biases, or both) based on minimizing a loss function. As one non-limiting example, the loss function may be a mean squared error loss function.

Training a neural network may include initializing the neural network, such as by computing, estimating, or otherwise selecting initial network parameters (e.g., weights, biases, or both). Training data can then be input to the initialized neural network, generating output as pTx pulse waveform data. The quality of the pTx waveform data can then be evaluated, such as by passing the pTx pulse waveform data to the loss function to compute an error. The current neural network can then be updated based on the calculated error (e.g., using backpropagation methods based on the calculated error). For instance, the current neural network can be updated by updating the network parameters (e.g., weights, biases, or both) in order to minimize the loss according to the loss function. When the error has been minimized (e.g., by determining whether an error threshold or other stopping criterion has been satisfied), the current neural network and its associated network parameters represent the trained neural network. In some embodiments, the neural network may be trained in part using a physics-based constraint. For instance, the physics-based constraint, such as those described above, may be integrated as part of the loss function used during neural network training.

In some embodiments, the neural network may be trained using a supervised learning approach, in which optimal pulses for the training dataset are computed or otherwise designed, and/or a B₁⁺ map from a single-channel is used during the training process. In some other embodiments, the neural network may be trained using an unsupervised learning approach using multichannel B₁⁺ maps and a mean square error (e.g., a root mean square error) loss function. In still other embodiments, a self-supervised learning approach can be used, such as those described in co-pending U.S. patent application Ser. No. 17/075,411, which is herein incorporated by reference in its entirety.

The one or more trained neural networks are then stored for later use, as indicated at step 406. Storing the neural network(s) may include storing network parameters (e.g., weights, biases, or both), which have been computed or otherwise estimated by training the neural network(s) on the training data. Storing the trained neural network(s) may also include storing the particular neural network architecture to be implemented. For instance, data pertaining to the layers in the neural network architecture (e.g., number of layers, type of layers, ordering of layers, connections between layers, hyperparameters for layers) may be stored.

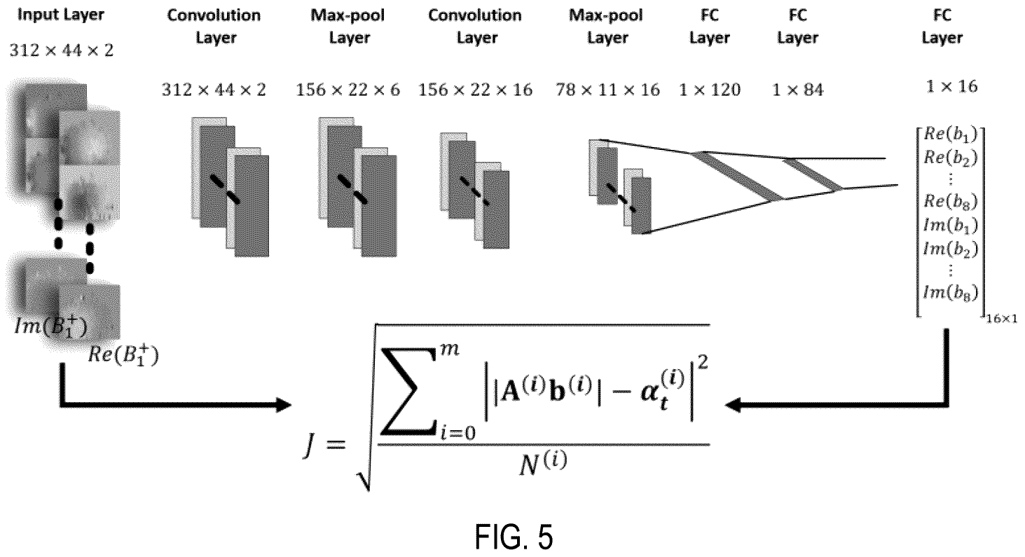

In an example implementation, an unsupervised deep learning technique was implemented for designing pTx pulses. In this example implementations, multichannel B₁⁺ maps were used as an input to a trained deep learning model, such as a trained neural network. For multichannel B₁⁺ maps, a concatenation of the channels along a third dimension may not be a well-designed input for a CNN, since there is no natural ordering of the channels at the input (i.e., any permutation is valid), whereas CNNs are not permutationally invariant. To address this challenge, the multichannel maps B₁⁺ (x,y,c) can instead be concatenated along the y-dimension to yield 2D data, B_{1,c}⁺ (x,y), thereby transforming the problem for shift-invariant processing, amenable to CNNs. For these complex maps, the real and imaginary parts can be given as different channels at input. In a non-limiting example the neural network used can be a feed-forward CNN, such as the one shown in FIG. 5. In this example neural network, convolutions and max-pool operations used 5×5 and 2×2 kernels, respectively, and a ReLU function was utilized for activation.

In this example, root mean square error (“RMSE”) was used for the loss function in the training process, as shown in FIG. 5. In the formula, for the ith training sample, A⁽ⁱ⁾ is the system matrix generated via the B₁⁺ maps for each coil at each spatial location vectorized as column vectors, b⁽ⁱ⁾ is the B₁⁺ complex shimming weights for each coil, αₜ⁽ⁱ⁾ is the target flip angle map, and N⁽ⁱ⁾ is the number of elements in the ROI. The dataset can be randomly split into training, validation, and testing datasets. For instance, the dataset can be randomly split into 80% training, 10% validation, and 10% testing datasets.

This unsupervised deep learning approach enables a training scheme that is more computationally efficient because it does not necessitate solving a complex optimization problem for pTx pulse design based supervision. Additionally, the proposed image domain concatenation at the network input addresses the difficulties that existing deep learning methods have with using multichannel B₁⁺ maps as an input. The trained deep learning approach is very fast, with an inference time on the order of a few milliseconds (e.g., ˜2 ms) in an example study.

Referring now to FIG. 5, an example of a system 500 for pTx or other RF pulse waveform design in accordance with some embodiments of the systems and methods described in the present disclosure is shown. As shown in FIG. 5, a computing device 550 can receive one or more types of data (e.g., magnetic resonance data, scout image data, field map data, multichannel B₁⁺ maps data) from image source 502, which may be a magnetic resonance image source. In some embodiments, computing device 550 can execute at least a portion of a pTx pulse waveform design system 504 to design pTx pulse waveforms from data received from the image source 502 (e.g., using the method described in FIG. 1 and/or the method described in FIG. 3).

Additionally or alternatively, in some embodiments, the computing device 550 can communicate information about data received from the image source 502 to a server 552 over a communication network 554, which can execute at least a portion of the pTx pulse waveform design system 504. In such embodiments, the server 552 can return information to the computing device 550 (and/or any other suitable computing device) indicative of an output of the pTx pulse waveform design system 504.

In some embodiments, computing device 550 and/or server 552 can be any suitable computing device or combination of devices, such as a desktop computer, a laptop computer, a smartphone, a tablet computer, a wearable computer, a server computer, a virtual machine being executed by a physical computing device, and so on. The computing device 550 and/or server 552 can also reconstruct images from the data.

In some embodiments, image source 502 can be any suitable source of image data (e.g., measurement data, images reconstructed from measurement data), such as an MRI system, another computing device (e.g., a server storing image data), and so on. In some embodiments, image source 502 can be local to computing device 550. For example, image source 502 can be incorporated with computing device 550 (e.g., computing device 550 can be configured as part of a device for capturing, scanning, and/or storing images). As another example, image source 502 can be connected to computing device 550 by a cable, a direct wireless link, and so on. Additionally or alternatively, in some embodiments, image source 502 can be located locally and/or remotely from computing device 550, and can communicate data to computing device 550 (and/or server 552) via a communication network (e.g., communication network 554).

In some embodiments, communication network 554 can be any suitable communication network or combination of communication networks. For example, communication network 554 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), a wired network, and so on. In some embodiments, communication network 554 can be a local area network, a wide area network, a public network (e.g., the Internet), a private or semi-private network (e.g., a corporate or university intranet), any other suitable type of network, or any suitable combination of networks. Communications links shown in FIG. 5 can each be any suitable communications link or combination of communications links, such as wired links, fiber optic links, Wi-Fi links, Bluetooth links, cellular links, and so on.

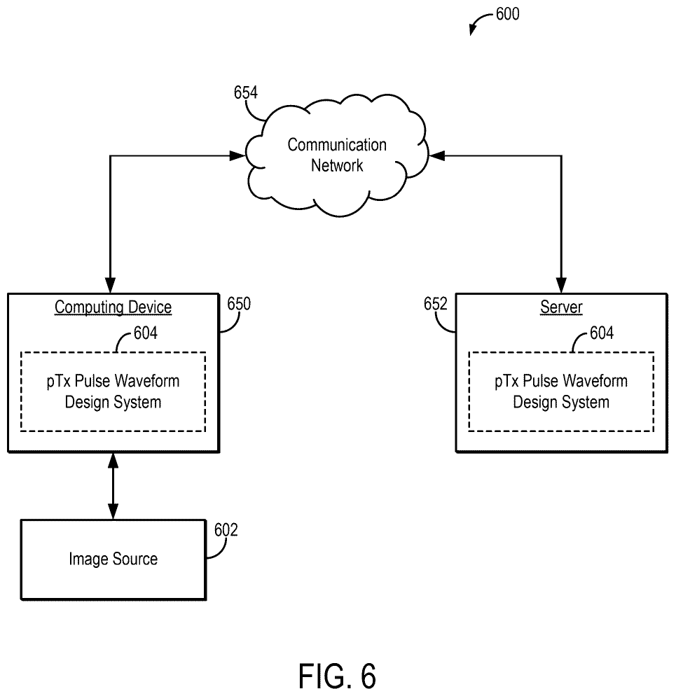

Referring now to FIG. 6, an example of hardware 600 that can be used to implement image source 502, computing device 550, and server 552 in accordance with some embodiments of the systems and methods described in the present disclosure is shown. As shown in FIG. 6, in some embodiments, computing device 550 can include a processor 602, a display 604, one or more inputs 606, one or more communication systems 608, and/or memory 610. In some embodiments, processor 602 can be any suitable hardware processor or combination of processors, such as a central processing unit (“CPU”), a graphics processing unit (“GPU”), and so on. In some embodiments, display 604 can include any suitable display devices, such as a computer monitor, a touchscreen, a television, and so on. In some embodiments, inputs 606 can include any suitable input devices and/or sensors that can be used to receive user input, such as a keyboard, a mouse, a touchscreen, a microphone, and so on.

In some embodiments, communications systems 608 can include any suitable hardware, firmware, and/or software for communicating information over communication network 554 and/or any other suitable communication networks. For example, communications systems 608 can include one or more transceivers, one or more communication chips and/or chip sets, and so on. In a more particular example, communications systems 608 can include hardware, firmware and/or software that can be used to establish a Wi-Fi connection, a Bluetooth connection, a cellular connection, an Ethernet connection, and so on.

In some embodiments, memory 610 can include any suitable storage device or devices that can be used to store instructions, values, data, or the like, that can be used, for example, by processor 602 to present content using display 604, to communicate with server 552 via communications system(s) 608, and so on. Memory 610 can include any suitable volatile memory, non-volatile memory, storage, or any suitable combination thereof. For example, memory 610 can include RAM, ROM, EEPROM, one or more flash drives, one or more hard disks, one or more solid state drives, one or more optical drives, and so on. In some embodiments, memory 610 can have encoded thereon, or otherwise stored therein, a computer program for controlling operation of computing device 550. In such embodiments, processor 602 can execute at least a portion of the computer program to present content (e.g., images, user interfaces, graphics, tables), receive content from server 552, transmit information to server 552, and so on.

In some embodiments, server 552 can include a processor 612, a display 614, one or more inputs 616, one or more communications systems 618, and/or memory 620. In some embodiments, processor 612 can be any suitable hardware processor or combination of processors, such as a CPU, a GPU, and so on. In some embodiments, display 614 can include any suitable display devices, such as a computer monitor, a touchscreen, a television, and so on. In some embodiments, inputs 616 can include any suitable input devices and/or sensors that can be used to receive user input, such as a keyboard, a mouse, a touchscreen, a microphone, and so on.

In some embodiments, communications systems 618 can include any suitable hardware, firmware, and/or software for communicating information over communication network 554 and/or any other suitable communication networks. For example, communications systems 618 can include one or more transceivers, one or more communication chips and/or chip sets, and so on. In a more particular example, communications systems 618 can include hardware, firmware and/or software that can be used to establish a Wi-Fi connection, a Bluetooth connection, a cellular connection, an Ethernet connection, and so on.

In some embodiments, memory 620 can include any suitable storage device or devices that can be used to store instructions, values, data, or the like, that can be used, for example, by processor 612 to present content using display 614, to communicate with one or more computing devices 550, and so on. Memory 620 can include any suitable volatile memory, non-volatile memory, storage, or any suitable combination thereof. For example, memory 620 can include RAM, ROM, EEPROM, one or more flash drives, one or more hard disks, one or more solid state drives, one or more optical drives, and so on. In some embodiments, memory 620 can have encoded thereon a server program for controlling operation of server 552. In such embodiments, processor 612 can execute at least a portion of the server program to transmit information and/or content (e.g., data, images, a user interface) to one or more computing devices 550, receive information and/or content from one or more computing devices 550, receive instructions from one or more devices (e.g., a personal computer, a laptop computer, a tablet computer, a smartphone), and so on.

In some embodiments, image source 502 can include a processor 622, one or more image acquisition systems 624, one or more communications systems 626, and/or memory 628. In some embodiments, processor 622 can be any suitable hardware processor or combination of processors, such as a CPU, a GPU, and so on. In some embodiments, the one or more image acquisition systems 624 are generally configured to acquire data, images, or both, and can include an MRI system. Additionally or alternatively, in some embodiments, one or more image acquisition systems 624 can include any suitable hardware, firmware, and/or software for coupling to and/or controlling operations of an MRI system. In some embodiments, one or more portions of the one or more image acquisition systems 624 can be removable and/or replaceable.

Note that, although not shown, image source 502 can include any suitable inputs and/or outputs. For example, image source 502 can include input devices and/or sensors that can be used to receive user input, such as a keyboard, a mouse, a touchscreen, a microphone, a trackpad, a trackball, and so on. As another example, image source 502 can include any suitable display devices, such as a computer monitor, a touchscreen, a television, etc., one or more speakers, and so on.

In some embodiments, communications systems 626 can include any suitable hardware, firmware, and/or software for communicating information to computing device 550 (and, in some embodiments, over communication network 554 and/or any other suitable communication networks). For example, communications systems 626 can include one or more transceivers, one or more communication chips and/or chip sets, and so on. In a more particular example, communications systems 626 can include hardware, firmware and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some embodiments, memory 628 can include any suitable storage device or devices that can be used to store instructions, values, data, or the like, that can be used, for example, by processor 622 to control the one or more image acquisition systems 624, and/or receive data from the one or more image acquisition systems 624; to images from data; present content (e.g., images, a user interface) using a display; communicate with one or more computing devices 550; and so on. Memory 628 can include any suitable volatile memory, non-volatile memory, storage, or any suitable combination thereof. For example, memory 628 can include RAM, ROM, EEPROM, one or more flash drives, one or more hard disks, one or more solid state drives, one or more optical drives, and so on. In some embodiments, memory 628 can have encoded thereon, or otherwise stored therein, a program for controlling operation of image source 502. In such embodiments, processor 622 can execute at least a portion of the program to generate images, transmit information and/or content (e.g., data, images) to one or more computing devices 550, receive information and/or content from one or more computing devices 550, receive instructions from one or more devices (e.g., a personal computer, a laptop computer, a tablet computer, a smartphone, etc.), and so on.

In some embodiments, any suitable computer readable media can be used for storing instructions for performing the functions and/or processes described herein. For example, in some embodiments, computer readable media can be transitory or non-transitory. For example, non-transitory computer readable media can include media such as magnetic media (e.g., hard disks, floppy disks), optical media (e.g., compact discs, digital video discs, Blu-ray discs), semiconductor media (e.g., random access memory (“RAM”), flash memory, electrically programmable read only memory (“EPROM”), electrically erasable programmable read only memory (“EEPROM”)), any suitable media that is not fleeting or devoid of any semblance of permanence during transmission, and/or any suitable tangible media. As another example, transitory computer readable media can include signals on networks, in wires, conductors, optical fibers, circuits, or any suitable media that is fleeting and devoid of any semblance of permanence during transmission, and/or any suitable intangible media.

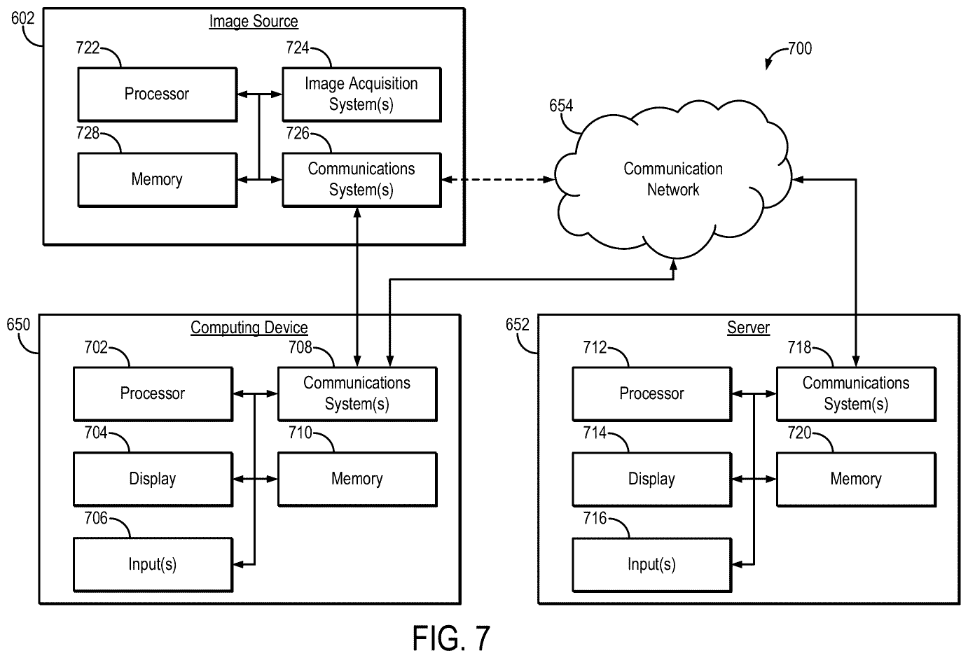

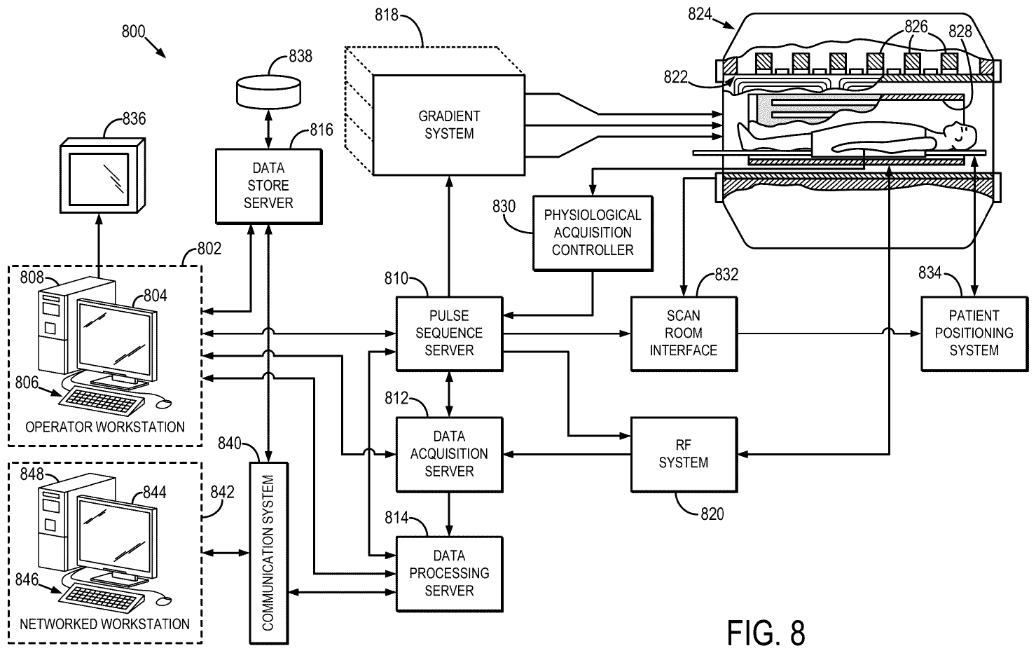

Referring particularly now to FIG. 7, an example of a magnetic resonance imaging (“MRI”) system 700 that can implement the methods described here is illustrated. The MRI system 700 includes an operator workstation 702 that may include a display 704, one or more input devices 706 (e.g., a keyboard, a mouse), and a processor 708. The processor 708 may include a commercially available programmable machine running a commercially available operating system. The operator workstation 702 provides an operator interface that facilitates entering scan parameters into the MRI system 700. The operator workstation 702 may be coupled to different servers, including, for example, a pulse sequence server 710, a data acquisition server 712, a data processing server 714, and a data store server 716. The operator workstation 702 and the servers 710, 712, 714, and 716 may be connected via a communication system 740, which may include wired or wireless network connections.

The pulse sequence server 710 functions in response to instructions provided by the operator workstation 702 to operate a gradient system 718 and a radiofrequency (“RF”) system 720. Gradient waveforms for performing a prescribed scan are produced and applied to the gradient system 718, which then excites gradient coils in an assembly 722 to produce the magnetic field gradients Gₓ, G_{y}, and G_{z} that are used for spatially encoding magnetic resonance signals. The gradient coil assembly 722 forms part of a magnet assembly 724 that includes a polarizing magnet 726 and a whole-body RF coil 728. In some configurations, the polarizing magnet 726 can be configured to generate a main magnetic field, B₀, having a so-called “high” field strength (i.e., B₀≥3T). In other configurations, the polarizing magnet 726 can be configured to generate a main magnetic field having a so-called “ultrahigh” field strength (i.e., B₀≥7T).

RF waveforms are applied by the RF system 720 to the RF coil 728, or a separate local coil to perform the prescribed magnetic resonance pulse sequence. Responsive magnetic resonance signals detected by the RF coil 728, or a separate local coil, are received by the RF system 720. The responsive magnetic resonance signals may be amplified, demodulated, filtered, and digitized under direction of commands produced by the pulse sequence server 710. The RF system 720 includes an RF transmitter for producing a wide variety of RF pulses used in MRI pulse sequences. The RF transmitter is responsive to the prescribed scan and direction from the pulse sequence server 710 to produce RF pulses of the desired frequency, phase, and pulse amplitude waveform. The generated RF pulses may be applied to the whole-body RF coil 728 or to one or more local coils or coil arrays.

The RF system 720 also includes one or more RF receiver channels. An RF receiver channel includes an RF preamplifier that amplifies the magnetic resonance signal received by the coil 728 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ; \qquad ( 2 )$$

and the phase of the received magnetic resonance signal may also be determined according to the following relationship:

$$φ = {tan}^{- 1} ( \frac{Q}{I} ) . \qquad ( 3 )$$

The pulse sequence server 710 may receive patient data from a physiological acquisition controller 730. By way of example, the physiological acquisition controller 730 may receive signals from a number of different sensors connected to the patient, including electrocardiograph (“ECG”) signals from electrodes, or respiratory signals from a respiratory bellows or other respiratory monitoring devices. These signals may be used by the pulse sequence server 710 to synchronize, or “gate,” the performance of the scan with the subject's heart beat or respiration.

The pulse sequence server 710 may also connect to a scan room interface circuit 732 that receives signals from various sensors associated with the condition of the patient and the magnet system. Through the scan room interface circuit 732, a patient positioning system 734 can receive commands to move the patient to desired positions during the scan.

The digitized magnetic resonance signal samples produced by the RF system 720 are received by the data acquisition server 712. The data acquisition server 712 operates in response to instructions downloaded from the operator workstation 702 to receive the real-time magnetic resonance data and provide buffer storage, so that data is not lost by data overrun. In some scans, the data acquisition server 712 passes the acquired magnetic resonance data to the data processor server 714. In scans that require information derived from acquired magnetic resonance data to control the further performance of the scan, the data acquisition server 712 may be programmed to produce such information and convey 1t to the pulse sequence server 710. For example, during pre-scans, magnetic resonance data may be acquired and used to reconstruct scout (or localizer) images.

The data processing server 714 receives magnetic resonance data from the data acquisition server 712 and processes the magnetic resonance data in accordance with instructions provided by the operator workstation 702. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, and the like.

Images reconstructed by the data processing server 714 are conveyed back to the operator workstation 702 for storage. Real-time images may be stored in a data base memory cache, from which they may be output to operator display 702 or a display 736. Batch mode images or selected real time images may be stored in a host database on disc storage 738. When such images have been reconstructed and transferred to storage, the data processing server 714 may notify the data store server 716 on the operator workstation 702. The operator workstation 702 may be used by an operator to archive the images, produce films, or send the images via a network to other facilities.

The MRI system 700 may also include one or more networked workstations 742. For example, a networked workstation 742 may include a display 744, one or more input devices 746 (e.g., a keyboard, a mouse), and a processor 748. The networked workstation 742 may be located within the same facility as the operator workstation 702, or in a different facility, such as a different healthcare institution or clinic.

The networked workstation 742 may gain remote access to the data processing server 714 or data store server 716 via the communication system 740. Accordingly, multiple networked workstations 742 may have access to the data processing server 714 and the data store server 716. In this manner, magnetic resonance data, reconstructed images, or other data may be exchanged between the data processing server 714 or the data store server 716 and the networked workstations 742, such that the data or images may be remotely processed by a networked workstation 742.

The present disclosure has described one or more preferred embodiments, and it should be appreciated that many equivalents, alternatives, variations, and modifications, aside from those expressly stated, are possible and within the scope of the invention.

1. A method for generating parallel transmit (pTx) radio frequency (RF) pulse waveforms for use with a magnetic resonance imaging (MRI) system, the method comprising:
(a) accessing field map data with a computer system, wherein the field map data indicate at least one B₀ field map associated with the MRI system and at least one B₁⁺ field map associated with an RF coil;
(b) constructing an optimization problem with the computer system, wherein the optimization problem comprises an objective function having at least one physics-based constraint;
(c) accessing a trained neural network with the computer system, wherein the trained neural network has been trained on training data in order to learn a mapping from field map data to parameters for improving an efficiency of solving a constrained optimization problem;
(d) applying the field map data to the trained neural network using the computer system, generating output as optimization parameter data that indicate parameters for improving the efficiency of solving the optimization problem constructed with the computer system;
(e) generating pTx RF pulse waveforms by using the computer system to solve the optimization problem based on the optimization parameter data; and
(f) storing the pTx RF pulse waveforms for use by the MRI system.

2. The method of claim 1, further comprising generating at least one RF pulse with the MRI system by operating the MRI system based on the stored pTx RF pulse waveforms.

3. The method of claim 1, wherein the at least one physics-based constraint comprises a specific absorption rate constraint.

4. The method of claim 1, wherein the at least one physics-based constraint comprises a power constraint.

5. The method of claim 1, wherein the at least one physics based constraint comprises at least one specific absorption rate constraint and at least one power constraint.

6. The method of claim 1, wherein the computer system solves the optimization problem by optimizing the objective function based on the optimization parameter data.

7. The method of claim 6, wherein the optimization parameter data indicate an optimal step size for improving the efficiency of solving the optimization problem.

8. The method of claim 6, wherein the optimization problem is solved using the computer system to implement an interior-point method to optimize the objective function.

9. A method for generating parallel transmit (pTx) radio frequency (RF) pulse waveforms for use with a magnetic resonance imaging (MRI) system, the method comprising:
(a) accessing magnetic resonance data with a computer system, wherein the magnetic resonance data have been acquired with an MRI system;
(b) accessing a neural network with the computer system, wherein the neural network has been trained on training data in order to learn a mapping from magnetic resonance data to pTx RF pulse waveforms;
(c) applying the magnetic resonance data to the neural network using the computer system, generating output as pTx RF pulse waveforms;
(d) storing the pTx RF pulse waveforms for use by the MRI system.

10. The method of claim 9, further comprising generating at least one RF pulse with the MRI system by operating the MRI system based on the stored pTx RF pulse waveforms.

11. The method of claim 9, wherein the magnetic resonance data accessed with the computer system include image data acquired with the MRI system.

12. The method of claim 11, wherein the image data accessed with the computer system include scout image data comprising scout images acquired with the MRI system.

13. The method of claim 12, wherein the scout images comprise anatomical images that depict subject anatomy.

14. The method of claim 11, wherein the neural network accessed with the computer system has been trained on training data consistent with the image data in order to learn the mapping from magnetic resonance data to pTx RF pulse waveforms based on field map data encoded in the image data.

15. The method of claim 9, wherein the magnetic resonance data accessed with the computer system comprise multichannel B₁⁺ map data comprising multichannel B₁⁺ maps.

16. The method of claim 15, wherein the neural network accessed with the computer system has been trained on training data consistent with the multichannel B₁⁺ map data in order to learn the mapping from magnetic resonance data to pTx RF pulse waveforms.

17. The method of claim 16, wherein the training data comprise multichannel B₁⁺ maps that are concatenated along a single spatial dimension such that the training data comprise two-dimensional data.

18. The method of claim 9, wherein the neural network accessed with the computer system has been trained on training data using a loss function that incorporates a physics-based constraint.

19. The method of claim 18, wherein the physics-based constraint comprises at least one of a specific absorption rate constraint or a power constraint.

20. A method for generating a radio frequency (RF) pulse waveform for use with a magnetic resonance imaging (MRI) system, the method comprising:
(a) accessing field map data with a computer system, wherein the field map data indicate at least one B₀ field map associated with the MRI system and at least one B₁⁺ field map associated with an RF coil;
(b) constructing an optimization problem with the computer system, wherein the optimization problem comprises an objective function having at least one physics-based constraint;
(c) accessing a trained neural network with the computer system, wherein the trained neural network has been trained on training data in order to learn a mapping from field map data to parameters for improving an efficiency of solving a constrained optimization problem;
(d) applying the field map data to the trained neural network using the computer system, generating output as optimization parameter data that indicate parameters for improving the efficiency of solving the optimization problem constructed with the computer system;
(e) generating an RF pulse waveform by using the computer system to solve the optimization problem based on the optimization parameter data; and
(f) storing the RF pulse waveform for use by the MRI system.

21. The method of claim 20, wherein the RF pulse waveform comprises a plurality of parallel transmit (pTx) RF pulse waveforms.

22. The method of claim 20, wherein the RF pulse waveform comprises a water-fat separation RF pulse waveform.
